(19) United States
(12) Patent Application Publication
(10) Pub. No.: US 2024/0063761 A1
(43) Pub. Date: Feb. 22, 2024

(54) Distortion system for guitar

(71) Applicant: Maria Luisa Cesario, ROMA (IT)

(72) Inventor: Maria Luisa Cesario, ROMA (IT)

(21) Appl. No.: 18/258,205

(22) PCT Filed: Dec. 22, 2021
(86) PCT No.: PCT/IT21/50423

§ 371 Date: Jun. 17, 2023

(30) Foreign Application Priority Data
Jan. 4, 2021 (IT) 102021000000065

(51) Int. Cl. H03F 3/183; G10H 3/18

(52) U.S. Cl. CPC H03F 3/183; G10H 3/187; G10H 2210/311; H03F 2200/03

(57) ABSTRACT

Concept and ways are described of implementing a sound distortion circuit suitable for musical instruments, in particular, for electric guitars. Inputting an audio signal, low noise intrinsic to the circuit electronics is provided to the output. This type of noise, here referred to as electroacoustic noise, is produced by the interaction of the harmonic components of the audio signal with the natural ways by which sound and heat propagate in materials that make up the circuit components. The invention demonstrates that this type of noise, not foreseen by prior art, presides over the musical quality of sound even when artificially distorted, as is often required especially by guitarists. Compared to the best that is offered by comparable prior art equipment, the invention offers the musician greater freedom of tonal research and also greater ease of musical performance, thanks to the greater degree of intonation obtainable with the instrument.

### TECHNICAL FIELD

The embodiments of the present description refer to the concept of distortion of electronically produced sound. The embodiments of the present description consist of a sound distortion device with low electroacoustic noise for musical instruments.

### BACKGROUND ART

For musicians, distortion tools are essential for creating effects by modifying the signal coming from the instrument's pick-up, as often required for expressive and artistic purposes. The signal still retains a certain imprint of original sound, but appropriate artefacts with desired intensity and character are added. The distortion tool should be connected at the input or at the external loop terminals (FX loop) of, e.g., a guitar amplifier, or should be available as a module incorporated into the amplifier embodiment itself.

A way for producing audio signal distortion is based on wave squaring effect, obtained making strong amplification so that a sinusoidal signal acquires quasi-triangular and then square wave shape for signal amplitudes more and more large, which corresponds to add artificial harmonic components, i.e., extraneous to audio signal. Consequently, overdrive regimes are obtained called: crunch, lead and even fuzz modes are made available for guitarists.

In addition to wave squaring, guitarists sometimes choose to alter the sound in other ways, such as, for example, the tremolo (obtained using an appropriate oscillator circuit), or the reverberation (reverb) mode. Hammond and then, under license, also Fender and other musical instrument manufacturers produced distortion tools for this mode. Reverb is obtained by inputting the signal coming from the musical instrument to an amplifier, for example, for guitar. The signal is preamplified and divided into two ways, the first of which does not involve any intentional alteration (it is the “dry” signal), while the second is connected to buffer stage that feeds the input of a device consisting of one or more springs, whose ends are connected to two electroacoustic transducers, respectively, the input and output of reverb device. The signal emerging from the device output is “wet” due to spring-produced resonances, and is then mixed with “dry” signal path. In any case, the general concept is the same, i.e., distortion system acts however by adding to harmonic components of the original signal, further of artificial type accordingly to musician needs.

This filing is motivated by the need to eliminate a type of noise intrinsic to prior art circuits, which leads to uncontrollable alteration of the sound, that is, to its homologation. Musicians and prior art experts are unaware of this phenomenon that impacts on harmonic and timbre qualities of a distortion tool, with detriment of musicians' freedom to truly find the type of sound sought. Such a problem derives from the occurrence of a phenomenon, which is referred to below as the electroacoustic noise intrinsic in electronics. This is illustrated below along with useful ways to suppress it.

Electroacoustic noise does not have anything to do with alterations to which prior art experts generally attribute euphonic properties (such as those produced by famous circuits aimed at replicating early guitar tube amplifiers), and it does not even have anything in common with artefact produced by modern solid-state circuitry that emulate electrical characteristics of tubes. The latter, according to prior art experts, would indeed give rise to euphonic defects of early guitar amplifiers. Since these defects occurred only for fortuitous reasons, prior art experts generally believe that sound performance much better would be obtained using sophisticated solid state circuits, owing to better accuracy of the emulation of valve characteristics of early all-tube amplifiers. This state of affairs is evidenced by patents even recent on the subject, including: “Method and apparatus for distortion of audio signals and emulation of vacuum tube amplifiers” by N. Gallo, US Pat. No. 20080218259A1 (2008), “Guitar Amplifier” US Patent No. 20130136278A1 by Quilter (2013), e “Vacuum Tube Amplification Unit”, US20150170627A1 by Hummel, (2015), “Semiconductor amplifier with tube amplifier characteristics”, U.S. Pat. No. 4,809,336A di Eric K. Pritchard (1987), “Solid state audio amplifier emulating a tube audio amplifier”, U.S. Pat. No. 5,467,400A by Bruce Keir, e pure in “Solid state circuit for emulating tube compression effect”, U.S. Pat. No. 5,524,055A Jack C. Sondermeyer, in “Solid state emulation of vacuum tube audio power amplifiers”, U.S. Pat. No. 5,636,284A di E. K. Pritchard (1994), in “Adjustable distortion guitar amplifier”, U.S. Pat. No. 4,495,640A, di Douglas R. Frey (1982).

However, since it is known that in any case guitarists continue to prefer circuits that reproduce those of early versions of guitar amplifiers, evidently the problem of the sound quality of electronics for musical instruments does not seem to have been solved.

Experts in the art have been continuing for about half a century to interpret this problem in terms of alleged listener's psychological-subjective reasons, according to which the ear would prefer a certain type of distortion considered euphonic, that is capable of embellishing the sound otherwise having a taste of ash, compared to original sound. Such unpleasantness would therefore be caused by a too low level of distortion, that is, by insufficient rate of euphonic distortion, see: “Tubes Versus Transistors”, R. O. Hamm, 43th Convention of the Audio Engineering Society, New York, Sep. 14, 1972. The idea according to which audio electronics should even add an appropriate type of distortion to the input signal, to make the reproduced sound more pleasant for subjective listening, has therefore been rooted for about five decades. Summing up, prior art therefore follows the idea that, both for clean and for distorted sound modes, circuits must necessarily be conceived by emulating the electrical characteristics of tubes to satisfy the taste of musicians. Since prior art solid-state circuit implementations produce a type of distortion whose sound qualities are generally not appreciated by musicians, we refer below only to prior art guitar distortions implemented with valves, as Gallo patent considers. Taken from the latter document, FIG. 1 shows an amplifier stage in which the tube is in the common cathode amplifier configuration generally used in the best prior art guitar amplifiers, which is also considered in prior art distortion circuits of renowned guitar equipment. On this basis, the electrical characteristics of strong wave squaring distortion are taken as a reference for emulation, and then implemented in solid-state circuit described in Gallo patent. With reference to FIG. 1, the input signal x (500) feeds the electron tube grid (502) and produces an output signal y (503). Since the latter is proportional to the difference x-v, where v depends on the anode current and in turn affects it, there is a negative feedback. The use of the technique of a conspicuous negative feedback rate together with the choice of tube circuitry adopting the common cathode configuration are considered by prior art to be indispensable elements for obtaining a certain type of sound, because, as said, such choices would cause the addition to the original signal of alterations that would lead the listener to judge the reproduced sound as having a higher quality. Furthermore, by means of a solid-state implementation of the type described in Gallo patent, guitarist could be able to dose with even greater effectiveness and flexibility than is possible with circuitry that merely reproduce early tube circuits. Furthermore prior art of guitar electronics generally uses metal film or mainly carbon mixture resistors. Some manufacturers believe that the latter would offer a better type of sound, without however specifying the reason; evidently, this choice is done with the intention of reproducing defects intrinsic of early apparatuses. However, as said, the problem remains unresolved whereby, on the one hand, prior art experts believe (according with the mentioned patents) that at the basis of the greater appreciation of the reproduced type of sound there would be, above all, the need to emulate intrinsic distortion characteristics of valves, while, on the other hand, musicians continue to prefer circuitry that harks back to early tube circuits rather than modern solid state implementations, claiming to fairly emulate valve characteristics.

The invention described below has finally managed to solve the problem.

### DISCLOSURE OF THE INVENTION

The invention consists in having identified technical means useful for making a distortion device for musical instruments, by which superior quality of the reproduced sound is obtained via suppressing electroacoustic noise.

The technical problem posed here does not thus consist in finding new ways to distort a musical signal, but in freeing the relevant known methods from adding further artifacts that cannot be managed by musician, because intrinsic to prior art electronics. The novelty is however important because it solves the problem of whether causes of psychological-subjective nature (as prior art experts generally believe), not of really objective/technical origin, would be what actually determines the quality of reproduced sound even by distortion systems. By the invention it is demonstrated that the psychological prior art interpretation is completely unsatisfactory and, consequently, its devices are easily outclassed in sound quality by apparatus that eliminates true physical effects whose existence prior art ignores.

Electroacoustic noise suppression techniques (which confer higher quality of even distorted sound, in the sense explained in the background art section), can be extrapolated to the general concept of distortion system for guitar or for other musical instruments, i.e. these techniques are valid both for wave squaring distortion (which allows to obtain the crunch, overdrive, lead and fuzz modes), as well as for producing reverb, tremolo, etc. modes. In fact, to produce all those distortion functions, prior art apparatuses use valve or solid-state circuits, however unsuitable for eliminating the electroacoustic noise.

The general validity of a low electroacoustic noise distortion system described here derives from not adding to audio signal any alteration different from that wanted by user thinking the known concepts of distorted sound (i.e., to harmonic components of the original signal are added others of an artificial type). The latter concept, however, only by invention is actually manageable by musician (even if he is not aware of it), since prior art experts too ignore that their apparatuses in any case introduce artifacts intrinsic to electronics. These artifacts consist in spurious harmonics unrelated to original audio signal and also to the type of distortion that is desired indeed. In any case, the same problem posed for a distortion system for musical instruments is solved here, that is, a higher quality of artificially altered sound is obtained thanks to electroacoustic noise elimination.

It might seem strange that with regard to system aimed at distorting the original signal, it is here posed as a preliminary condition to reproduce the sound as closely as possible to the original audio signal. This, considering that user would want to alter the signal even in a very marked way, until it is almost unrecognizable with respect to original sound signal. In reality, this actually makes sense because it is reasonable that user has to be the master of imposing any kind of artifact in the sound, without the latter being affected by any homologated character, i.e., imposed by unmanageable effects intrinsic to circuitry, or imposed by engineers albeit for an alleged idea of embellishing the sound.

Homologation character, however inflicted on the signal, conflicts with indispensable requirements of expressive freedom of musicians. This cannot be respected with prior art circuits not only because they are still affected by electroacoustic noise, but because, precisely to try to eliminate the unpleasantness that derives from such noise, manufacturers generally force the sound to be wrapped from a sort of veil of embellishment. This, as said, reflects purposed obligatory claim to re-propose circuits like those of early guitar electronics, or to replicate alleged beneficial defects by emulating the characteristics of tubes via sophisticated solid-state circuits.

The invention described here presents harmonic characteristics of better quality than those obtainable with prior art apparatuses, because circuitry strictly treats in the same way both the harmonic components that characterize the original audio signal and the artificial ones really chosen by musician, since alterations associated with electroacoustic noise are eliminated. It is therefore a radically different approach to that considered in mentioned patents, all aiming at altering the audio signal by adding artefacts alleged to have euphonic properties.

The goal of the invention is achieved both by avoiding adding any type of alteration (however presumed to be of a euphonic type) and also using technical choices suitable to eliminate the electroacoustic noise. It is a phenomenon intrinsic in the interaction of audio signal harmonics with the natural ways in which sound and heat propagate in materials making up the circuit components. Since slectroacoustic noise originates in the presence of a signal very rich in harmonic components such as for even trivial audio signal, the consequent alterations are not detectable by instrumental measurements, but only via listening tests in which the invention is compared with similar prior art apparatuses. Such a comparison shows indeed that a cause completely different from a psychological-subjective nature one, but of a technical-physical-objective type, is what that actually presides over the quality of sound reproduced by electronics.

Electroacoustic noise has an electromechanical nature (because it is linked to physics of the natural modes of sound and heat propagation in materials). It presents an analogy with microphonic effect of electronic components, with the difference, however, that the latter is produced from causes external to circuit, while electroacoustic noise is produced by phenomena occurring on a microscopic scale, inside the material that constitutes the circuit components. Due to the natural diffusive character of the propagation of sound and heat, this type of noise is led to pervade the entire circuit not only the so-called “signal path” which thus looses sense. Consequently techniques having a high rejection to common mode (of the type of those useful for suppressing electrical grid noise) are also appropriate for attenuating electroacoustic noise. Differential type circuit topologies are thus useful, such as those considered in: “Differential-input amplifier circuit” U.S. Pat. No. 4,272,728A by H A Wittlinger, “Differential amplifier” by K. Ishiguro, Y. Takahashi, US patent 2010/001797A1, and “Amplifying an audio signal”, by D. J. Mate, US 2008/008335A1.

Contrary to what prior art makes, for example, with regard to circuit of FIG. 1, the invention avoids using negative feedback because alters phase harmonic components, which instead must be returned in their integrity as regards both the original and distorted sound.

The circuit thus exclusively uses differential type amplifier stages without negative feedback, and electroacoustic noise is further suppressed by full differential type topology of circuit, which produces cancellation of common mode, whose type the electroacoustic noise shows belonging to.

In each long tailed pair differential amplifier stage, as well as in buffer stages necessary to connect the distortion tool to an audio chain, in order to help achieving lower electroacoustic noise at the output, it is necessary to use constant current sources that not merely consist of a simple resistor, but comprise constant current source devices of the active type. In fact, in this way a system (e.g., electrodes of tubes and respective connected circuit components) is created, more resilient to electromechanical stresses that occur on a microscopic scale, in the materials making up the circuit components.

The abovementioned criteria are to be understood as preparatory in order to more easily reveal the role of the following further technical choices, each of which contributes to further reduce the noise in object, which actually has an additive (electroacoustic and electromechanical) character. Therefore, in order to present higher mechanical stiffness useful for generating lower electroacoustic noise, the circuit uses wire-wound type resistors and potentiometers whose resistive element has a thickness as large as possible, so the value of the resistors used is maximum 100 kohm (unlike the much higher values sometimes used by prior art in guitar amplifier circuits and distortions). Besides larger mass, also a cross section of round shape of the resistive element is important to enhance mechanical stiffness and, consequently contribute to suppress electroacoustic noise.

To solve the same problem, capacitors have armatures with cylindrical geometry, that is, they are of the axial type, and dielectric of the non-electrolytic type and with good mechanical consistency and relatively low dielectric constant. Capacitors are used only for inter-stage coupling, differently from prior art case of FIG. 1 (which actually uses C capacitor also to remove “degeneration” for audio frequencies in common cathode configuration of tube 502, by short-circuiting R resistor). Therefore, capacitor working voltage is as high as possible because in this way the component lends itself to being mechanically stiffer, thus less prone to generate electroacoustic noise. This choice is simple and inexpensive compared to that of opting for capacitors of special type, as manufactures of famous apparatuses often do. Such axial type capacitors with polyester or polypropylene dielectric even equipped with metal plates with a thickness (≥0.4 mm) greater than current realizations, lower generation of electroacoustic noise would result, so that those components really represent components especial devoted for music (audio) purposes.

The same type of circuit is used for electron tube, solid state, or mixed implementations. Electronic tubes having an appropriate geometry of electrodes and circular mechanical supports, since they are intrinsically more mechanically stiff, they are less prone to generate electroacoustic noise than others in which parallelepiped geometry dominates. Prior art valve implementations generally do not however specify the type of structure of tube electrodes. Solid-state implementation of the invention involves the use of discrete components, i.e., they must not be integrated circuits. The size of the active region must be as large as possible, as suitable for high voltages and high powers.

Active cooling of the case of circuit (not tube) components, at least ten degrees below the room temperature, leads to a significant reduction of electroacoustic noise, since, as mentioned, the interaction that produces the phenomenon depends on the natural ways in which heat propagates in the crystals constituting those devices.

The use by prior art of many stages in cascade, of the type shown in FIG. 1, represents in itself condition facilitating electroacoustic noise production and the output. This happens due to the use of both feedback and asymmetrical circuit topology, so that even an appropriate solid-state circuit designed to reduce electroacoustic noise (even not using active cooling) allows to outclass in sound quality also the best tube guitar amplifiers with distortion tool embedded, to which the invention is compared.

### BRIEF DESCRIPTION OF THE FIGURES

FIG. 1. Typical prior art circuit configuration of a tube-implemented guitar distortion module: voltage amplifier stage

FIG. 2. Typical prior art circuit configuration of a tube-implemented guitar distortion module: strong distortion stage.

FIG. 3. Wiring diagram of an embodiment of a guitar distortion tool with low electroacoustic noise.

FIG. 4. Conceptual diagram of an amplifier circuit in which the distortion system is equipped in order to better detect its musical performance.

### BEST MODE FOR CARRYING OUT THE INVENTION

Here are shown techniques useful to eliminate electroacoustic noise in a distortion. The principle of wave squaring is considered as main example, and same criteria can be easily extrapolated to other distortion principles for musical instruments.

To better illustrate the ways of realizing the invention, it is however necessary to analyze the operation of a typical example of prior art wave squaring guitar distortion, and then compare it with comparable way of realizing the invention.

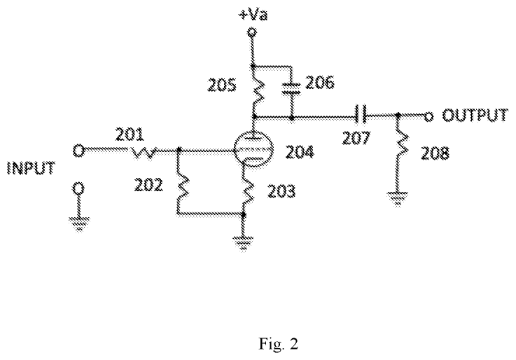

Referring to FIG. 2, resistor 603 on the cathode of the tube 604 has a quite high value, generally equal to about half of that (605) connected to anode (˜100 kohm), as it is necessary to polarize the tube with very low anode current for the device to operate in conditions very close to the cut-off (as required for an easy achievement of the stage saturation regime, then, strong distortion under even low amplitudes of the input signal). Such high value of cathode resistor 603 is associated with negative feedback rate which is very high too: this condition is considered useful for stabilizing the stage and avoiding the problems associated with operating too close to the cut-off condition of the tube. So, prior art makes extensive use of negative feedback to produce some opposition to changes in grid voltage consequent to input signal: the latter is consequently enabled to reach even quite large values, as necessary to accomplish distortion function. In fact, as mentioned above, the stage is located in circuit position useful to feed the “master” or “volume” potentiometer, which serves attenuating the signal level from several tens of volts to one volt, or a little more, as necessary to drive the output power stage of amplifier.

More in detail, biasing tube 604 of FIG. 2 with about 0.1 mA (as usually set), the reaction potential in the input mesh is typically about +4 V (for normal tubes under anode power supply voltages of about 300V). For null level of the input signal, this condition corresponds to a grid-cathode voltage compatible with that anode current, so Vgk is approximately equal to −4V. For moderately negative potentials of the input signal (Vin>−0.5V) the anode current decreases until it reaches a socket under which (i.e. for further more negative values, Vin≤−0.5V), the potential Vk remains fixed at a certain positive value, which corresponds to the residual anode current due to the shielding limit of the grid potential. For example, this residual anode current for a ECC88 triode is about 50 uA. For small signals, therefore, the potential on feedback resistor 205 offers some opposition to variations in the grid potential, as said, thus providing a certain stabilization effect of the working point.

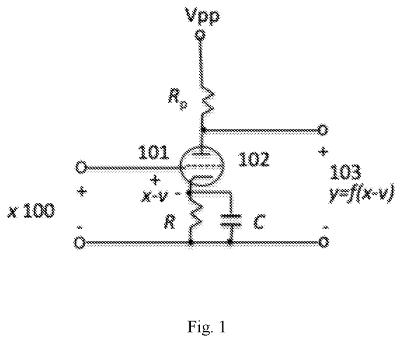

Consequently, with circuit of FIG. 2 it is possible to obtain the desired squaring function only over one side of signal waveform, that is the upper one that corresponds to values of the input signal having sufficiently negative amplitude (typically Vin≤−0.5V). For positive values of the signal, however, there is a departure from the cut-off condition, whereby anode current is favored and the output starts to follow fairly the waveform of the input signal. At the output it is therefore only exhibited a semi-wave squaring effect, while in order to complete the squaring function it is necessary to properly connect in cascade the anode of tube 604 to input of at least a couple of voltage amplifier stages of the type in FIG. 1, as generally done indeed by prior art. Importantly, resistor 601 and also resistors connected to grids of voltage amplifier stages (of the type of that of FIG. 1) connected in cascade, are chosen by prior art with large values (about 1 Mohm), in order to keep the grid current low for unwanted conditions in which the potential of the electrode reached positive values with respect to the cathode. This however contributes significantly to increasing electroacoustic noise caused by such types of not suitable resistors. Capacitor 606 has the function of preventing instability by narrowing the frequency band, which has the consequence of imposing a certain rounding of the portions corners of waveform subject to squaring, with impact of an alteration of harmonic components expected for such distortion function.

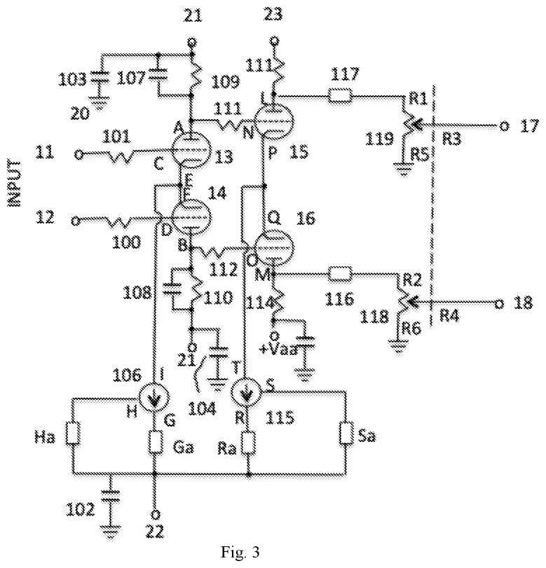

A way to make a low electroacoustic noise distortion circuit is shown in FIG. 3. Differential amplifier configuration (which includes the devices 13, 14 and the respective constant current sources which includes the device 106) performs a function similar to the one accomplished by by prior art common cathode amplifier circuits of FIG. 1 and FIG. 2.

To fix the operating point of circuit, a sufficiently low bias current (about 0.2 mA) is imposed by constant current source comprising constant current source device 106. The use of such current source allows avoiding the instability shortcoming mentioned with regard to circuit of FIG. 2, because forced to operate too near cut-off. This problem made it indispensable in such prior art embodiment the use of strong negative feedback rate, which in the invention is instead avoided.

The circuit of FIG. 3 allows obtaining symmetrical squaring of input waveform without the use of connecting many amplifier stages in cascade of the type of that in FIG. 1, as prior art generally does. Symmetrical wave squaring, indeed, is already obtained on anode signals of elements 13, 14 of FIG. 3, which have the same amplitude and opposite phases, as a result of the fact that those elements operate with the total current of anodes fixed by constant current source (which comprises the device current source 106).

To make available, therefore, complete wave squaring already at the output of distortion stage (terminals A, B of distortion devices 13, 14 of FIG. 3) allows to save on the number of amplifier stages and even to reach the goal of a simple distortion tool with low electroacoustic noise for musical instruments.

To outputs of distortion stage of FIG. 3 is connected in cascade, by connecting means 111, 112, to similar long tailed pair circuits, with voltage amplifier stage function (built with the same criteria for low electroacoustic noise), comprising devices 15, 16 and relative constant current source, comprising constant current source device 115. This stage increases the amplitude of distorted signal be suitable for driving the output power stage of an amplifier chain, which in turn feeds the speaker. Variable resistors 118, 119 of FIG. 3 have the function of volume control (master) regarding the signal driving the power stage of the guitar amplifier that incorporates the distortion module.

Filter capacitors (103, 104) of the DC supply voltage are of the type indicated above and are placed as close as possible to the supply terminals of the voltage amplifier devices. Furthermore, resistors 111 and 112 can be replaced by short circuits in case the long tailed pair differential amplification stages are implemented with tubes.

Since wire-wound resistors are quite inductive intrinsically, it is necessary to pay attention to noise of the electrical network coming from the power supply. In this regard, it is useful to place it quite distantly from the amplification stags, which also has the important further advantage of naturally reducing the contribution to electroacoustic noise given by the components of the power supply, in particular, by the electrolytic capacitors. filter and rectification devices of the ac voltage.

A problem similar to the aforementioned prior art one, concerning need for capacitor 606 in circuit of FIG. 2 to prevent instability, does not subsist with circuit of FIG. 3. In fact capacitors 107, 108 can be removed, because the circuit is inherently stable, and eventually used only for helping to determine the frequency band of distortion system.

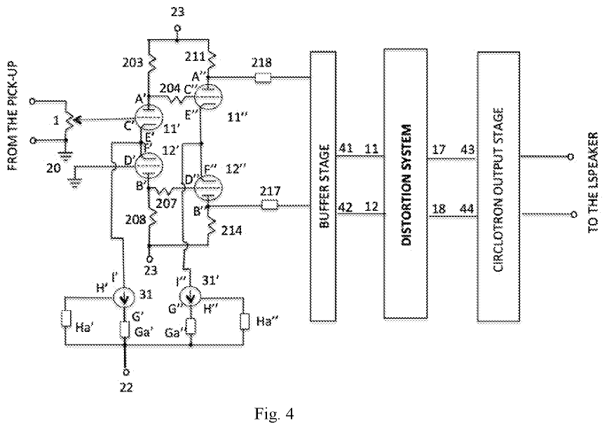

The electrical and conceptual scheme of FIG. 4 shows an amplifier chain useful for better reveal the tonal and harmonic characteristics of low electroacoustic noise distortion system as the one shown in FIG. 3. Even circuits in FIG. 4 are made considering the same criteria for low electroacoustic noise.

With reference to the latter figure, the level of the signal coming from the musical instrument is adjusted with the variable gain resistor (1) whose third terminal is connected to the ground terminal (20). This signal is generally of the single-ended type and is made of the balanced type to be used, after voltage preamplification, at the input of the distortion circuit.

The preamplification is obtained, as usual in the filing, by means of one or more long tailed pair differential stages, connected in cascade. These comprise, respectively, the devices 11′, 12′ and the relative constant current source which comprises the constant current source device 31, and the devices 11″, 12″ and the relative constant current source which comprises the source device of constant current 31′.

The output of voltage preamplifier stage of amplifier chain is connected by connection means (217, 218) to buffer stage, whose balanced signal outputs (41, 42) are connected to inputs of distortion circuit (11, 12, in case circuit of FIG. 3 is used as distortion tool). The outputs (17, 18) of the latter circuit are connected to inputs (43, 44) of the output power stage of amplifier chain. Such stage includes at least a module using Circlotron circuitry which, for tube or solid state implementation, is respectively described in: U.S. Pat. No. 2,705,265, Hall (1955) “Parallel Opposed Power Amplifiers”, and in U.S. Pat. No. 4,229,706A, Bongiorno (1980) “Audio amplifier”. However, these circuits, as such, are not sufficient to produce low electro-acoustic noise, but must be suitably optimized for the purpose in order to: a) be driven with differential amplifier circuits with symmetrical topology, b) use electronic components with suitable construction characteristics, and c) operate in suitable current and working temperature conditions. Details are provided in filing No. 102021000029834 (2021) by Cesario.

A similar distortion system for guitar can be used also for other musical instruments, and implemented with triodes or extrapolated for a solid-state implementation, for example mosfet. The wider the consideration of the criteria described above (on the circuit topology and on the construction details of the components), the better the result of a lower electroacoustic noise and, consequently, of a much higher quality of reproduced sound.

In the case of mosfet implementation, due to greater intrinsic gain that this type of components generally have, and owing to the lack of the aid provided by negative feedback, it is necessary to provide appropriate frequency equalization along the signal line in order to compensate for the drop in response for high frequencies. Also this last type of circuit, like any other dedicated to audio circuitry and its power supply, for reasons described above, must be made taking into account the mentioned criteria of low electroacoustic noise.

The input stage of the chain shown in FIG. 4, has preamplification function obtained by means of one or more long tailed pair differential stages connected in cascade, of the type of that of FIG. 3. Such stage comprises the amplifier devices 15, 16 and the respective constant current source comprising the device 115.

The input preamp stage has the second device of long tailed pair with the respective control terminal (grid/gate) connected to ground. In case the pick-up or microphone provide a balanced type signal, a dual gain potentiometer will be required and both control terminals of the long tailed pair devices of the input preamplifier stage will be used in the usual balanced signal way. The circuit exclusively employs amplifier stages of the differential type without negative feedback, as shown in FIG. 3: the absence of negative feedback causes a significant contribution to the electroacoustic noise to be lacking, while the differential type amplification produces some cancellation of the contributions generated for intrinsic reasons by the circuit components. The criteria of avoiding feedback technique and using symmetrical circuit topology are intended as preparatory in order to more easily reveal the role of further technical choices regarding the types of electronic components as well as their operating conditions of tcurrent polarization temperature, etc. Each choice contributes to further reduce electroacoustic noise, which has an additive character indeed.

As said, in replacement of wave squaring device of FIG. 3, buffer stage of the amplifier chain of FIG. 4 can feed also other types of distortion tools, e.g., a spring unit to produce the reverb mode. In fact, even the latter type of distortion acquires the special feature of invention, i.e., low electroacoustic noise and consequent superior tone performance: this holds provided that the same criteria described for the circuit of FIG. 3 are used. In particular, the networks necessary for regulating wet and dry signals to be mixed together for obtaining reverb mode must be made using: i) the same type of balanced signal circuits, ii) differential type amplification stages, iii) appropriate buffer circuits for the necessary balanced signal paths, iv) no feedback, etc.

In case the pick-up or microphone used to supply the input of circuit of FIG. 4 provide already a balanced type signal, dual potentiometer is required for gain regulation, in which the second section has the second terminal connected (in place of ground) with control terminal (grid) of second device (12′) of the input long tailed pair stage.

In summary, the same criteria described here are useful for suppressing electroacoustic noise from a distortion tool, based on wave squaring (to obtain the crunch, overdrive, lead and even fuzz modes), as well as considering also other concepts. In fact, the most renowned prior art means for sound quality, useful for obtaining sound alterations, generally use circuitry of the type of FIG. 1 and FIG. 2 to amplify the audio signal and drive the devices required for distorting sound for musical instruments.

In order to avoid that electroacoustic noise is added to the signal, with consequent detriment of harmonic characteristics of the wanted distorted sound, it is essential to use circuits and components of suitable type as described here.

What is claimed is:

1. A guitar distortion system implemented in electronic tubes or solid state devices which is characterized by low electroacoustic noise and comprises the following portions: i) at least first and second input terminal means (11,12) suitable to receive at least an input signal, ii) at least a long tailed pair distortion stage comprising at least first and second distortion device (13,14), iii) at least a long tailed pair voltage amplifier stage comprising first and second voltage amplifier device (15,16), iv) at least an output stage comprising at least first and second connecting means (117,116), at least first and second variable resistor (118,119), v) at least first and second output terminal means (17,18) suitable for connecting the distortion system to the input of a suitable amplifier circuit, and vi) ground terminal (20),
said electron tubes having at least a first portion called anode, at least a second portion for the thermal dissipation of the anode and at least a third mechanical support portion of the anode,
said first and second distortion devices (13,14) each comprising first and second input terminal (A,B), first and a second control terminal (C,D), first and second output terminal (E,F), constant current source, the latter comprising at least a constant current source device (106) comprising power supply terminal (G), control terminal (H) and output terminal (I),
said first and second input terminals (A,B) of said first and second distortion devices (13,14) being respectively connected by connection means to the same first source of DC voltage (21) referred to ground terminal (20),
said first and second control terminals (C,D) of said first and second distortion devices (13,14) being connected by respective connection means (101,100) to said first and second input terminal means (11,12),
said first and second output terminals (E,F) of said first and second distortion devices (13,14) being connected both to each other and to said output terminal (I) of said constant current source device (106) of said constant current source of said distortion stage,
said power supply terminal (G) of said constant current source device (106) being connected with connection means (Ga) to a second DC voltage source (22) referred to ground (20),
said control terminal (H) of said constant current source device (106) being connected by connection means (Ha) to said second DC voltage source (22),
said first and second voltage amplifier devices (15,16) each comprising: i) first and second input terminal (L,M), first and second control terminal (N,0), first and second output terminal (P,Q), ii) a constant current source comprising a constant current source device (115), the latter comprising power supply terminal (R), control terminal (S) and terminal output (T),
said first and second input terminals (L,M) of said first and second voltage amplifier devices (15,16) being respectively connected by connection means to the same third DC voltage source (23) referred to ground terminal (20),
said first and second control terminals (N,O) of said first and second voltage amplifier devices (15,16) being connected by respective connection means (111,120) to said first and second input terminals (A,B) of said first and second distortion device (13,14) of said distortion stage,
said first and second output terminals (P,Q) of said first and second voltage amplifier devices (15,16) being connected both to each other and to said output terminal (T) of said constant current source device (115) of said constant current source of said voltage amplifier device of said voltage amplifier stage,
said power supply terminal (R) of the last said constant current source device (115) being connected by connection means (Ra) to said second DC voltage source (22),
said control terminal (S) of the last said constant current source device (115) of the last said constant current source being connected by connection means (Sa) to said second DC voltage source (22),
said first and second variable resistor (118,119) of said output stage each comprising first terminal (R1,R2), second terminal (R3,R4) and third terminal (R5,R6),
said first and second connection means (117,116) of said output stage being respectively connected from said first and second input terminals of said first and second voltage amplifier device (15,16) to said first terminals (R1,R2) of said first and second variable resistor (118,119),
said second terminals (R3,R4) of said first and second variable resistor (118,119) being connected by means of connection to said first and second output terminal means (17,18), said portions of distortion system comprising at least a resistor or a capacitor.

2. A distortion system as in claim 1 wherein said resistor is of the wire wound type whose resistive element has thickness of at least 5 thousandths of millimeter.

3. A distortion system as in claim 1 wherein at least one of said variable resistors is of the wire wound type whose resistive element has thickness of at least one thousandth of millimeter.

4. A distortion system as in claim 1 wherein at least one of said solid state devices is suitable to withstand a drain-source or collector-emitter voltage of over 120 volts.

5. A distortion system as in claim 1 wherein at least one of said solid state devices is suitable to withstand collector or drain current levels of at least three amperes.

6. A distortion system as in claim 1 which includes a heat pump device comprising a first portion that absorbs heat, second portion which emits heat, and at least first and second power supply terminals connected to power electric source,
the case of at least one of said devices, or said resistors, or said capacitors comprised in said portions of distortion system being kept in contact with said first portion of said heat pump device, keeping said case cooled beyond five degrees below room temperature.

7. A distortion system as in claim 1 in which at least said portion called anode or said heat dissipation portion of the anode or said mechanical support portion of the anode has a curved shape for at least more than one third of the total surface of the portions themselves.

8. A distortion system as in claim 1 in which at least one of said electron tubes is polarized with an anode current equal to at least two thirds of the maximum allowed by the central design value of said electron tube.

9. A distortion system as in claim 1 in which said capacitor is of the non-electrolytic type, has armatures with a curved shape and a working voltage of at least 600 volts.

10. A distortion system as in the preceding claim in which said capacitor has a dielectric of the polyester or polypropylene type.
